(19) United States
(12) Patent Application Publication
(10) Pub. No.: US 2013/0115869 A1
(43) Pub. Date: May 9, 2013

(54) DIRECTED SERVER RACK AIR FLOW

(71) Applicants: Shareef F. Alshinnawi, Durham, NC (US); Robert W. Stegner, Raleigh, NC (US); Edward S. Suffern, Chapel Hill, NC (US); J. Mark Weber, Wake Forest, NC (US)

(72) Inventors: Shareef F. Alshinnawi, Durham, NC (US); Robert W. Stegner, Raleigh, NC (US); Edward S. Suffern, Chapel Hill, NC (US); J. Mark Weber, Wake Forest, NC (US)

(73) Assignee: INTERNATIONAL BUSINESS MACHINES CORPORATION, Armonk, NY (US)

(21) Appl. No.: 13/289,435

(22) Filed: Nov. 4, 2011

(51) Int. Cl. H05K 5/02; F24F 7/00; F24F 13/02

(52) U.S. Cl. 454/184; 454/284

(57) ABSTRACT

A user-customizable air guide comprises a duct having four side panels, an open front end, an open back end, and a flange extending from at least two of the side panels at the front end. The four side panels have a plurality of frangible links that are generally parallel and spaced apart along the rectangular duct between the front end and the back end, wherein each frangible link extends around the four side panels of the rectangular duct. The frangible links are manually breakable to customize the length of the duct extending from the open front end.

### BACKGROUND

1. Field of the Invention

The present invention relates to a kit for customized fabrication of an air guide to direct air flow within a computer server rack.

2. Background of the Related Art

Electronic components that make up computer systems consume electricity and generate heat. Heat-generating electronic components, such as processors, are generally supported within a server chassis. Multiple server chassis and other information technology equipment are placed/configured in rack in an efficient and stacked storage arrangement. Multiple racks may be arranged in a data center to form a cold air aisle and a hot air aisle. Cold air is introduced into the cold air aisle of the server rack and fans within the rack move the cold air through the electronic components supported within the server rack. The cold air takes on heat from the electronic components and becomes hot. The hot air exits the rack to a hot air aisle where the air may be removed from the room and returned to a computer room air conditioner (CRAC).

The dimensions of rack-mountable electronic components conform to specifications intended to provide interchangeability. Accordingly, the electronic components generally have a thickness that is an integer number of “units” or “U”s. For example, a typical rack-mountable electronic component may have a thickness of 1 U or 2 U. The components are generally of the same width in order to make the components supportable by uniformly spaced brackets coupled to opposed vertical walls of the server rack, but half-width components are also known. The length of the electronic components, however, may vary within the limited dimensions of the rack. As a result, the intake ends of electronic components supported within the server rack, which are disposed towards the cold air aisle, may present an irregular profile. Accordingly, the delivery of air flow from the cold air aisle to electronic components of shorter lengths may be impaired by head loss arising from the irregular profile.

FIG. 1 illustrates the problem of distributing cooling air flow to a number of electronic components 2-7 having varying lengths. A server rack 10 generally comprises a front 12 and a rear 14. Cold air is drawn from a cold air aisle 8 through the front 12 of the rack 10, for example using a fan disposed adjacent to the rear 14 of the rack 10 adjacent to a hot air aisle 9. The cold air passes through electronic components 2-7 en route from the front 12 to the rear 14 of the rack 10.

Due to the varying lengths of the electronic components 2-7, unwanted head loss impairs distribution of cooling air flow from a cool air aisle 8 near the front 12 of the server rack 10 to the shorter electronic component 5 that is more distant from the cool air aisle 8 than the longer components 2-4, 6, 7. Specifically, the cool air flow in path 16, designated for component 4, “piles” against component 4 and spills off of component 4 to disrupt adjacent path 18 that is designated for the shorter component 5. The resulting in impairment of the rate of cool air flow to component 5 causes portion 19 of the cool air flow 18 designated for component 5 to be diverted to component 4. As a result, the remaining air flow to component 4 in path 17 is insufficient, and the operating temperature of component 5 may be higher than optimal thereby resulting in a loss of performance.

### BRIEF SUMMARY

An embodiment of the present invention provides a user-customizable air guide. The air guide comprises a duct having four side panels, an open front end, an open back end, and a flange extending from at least two of the side panels at the front end. The four side panels have a plurality of frangible links that are generally parallel and spaced apart along the rectangular duct between the front end and the back end, wherein each frangible link extends around the four side panels of the rectangular duct. The frangible links are manually breakable to customize the length of the duct extending from the open front end.

### BRIEF DESCRIPTION OF THE SEVERAL VIEWS OF THE DRAWINGS

FIG. 1 is a side view of a server rack supporting heat-generating electronic components 2-7 of varying lengths in a “stacked” configuration.

FIG. 2 is a perspective view of a planar member having a plurality of parallel frangible links.

FIG. 3 is a partial perspective view of the planar member with linear perforations serving as alternative transverse frangible links and longitudinal frangible links.

FIG. 4 is a perspective view of an air guide having an inlet and an outlet.

FIG. 5A is a perspective view of the rectangular air guide with a corner between the two side panels torn from the back edge up to the first transverse frangible link.

FIG. 5B is a perspective view of the rectangular air guide with the portion folded upward to where it can be broken off.

FIG. 6 is a partial cross-sectional side view of the rack of FIG. 1 after installation of the air guide into the rack in alignment with the electronic component.

FIG. 7 is a perspective view of the front end of the air guide with its two flanges folded laterally and extending across the front of the vertical rails at the front of the rack.

### DETAILED DESCRIPTION

One embodiment of the present invention provides a user-customizable air guide. The air guide comprises a duct having four side panels, an open front end, an open back end, and a flange extending from at least two of the side panels at the front end. The four side panels have a plurality of frangible links that are generally parallel and spaced apart along the rectangular duct between the front end and the back end, wherein each frangible link extends around the four side panels of the rectangular duct. The frangible links are manually breakable to customize the length of the duct extending from the open front end.

The customizable air guide can be fabricated to fit in a server rack to direct cold air flow and to promote optimal distribution of cold air flow among heat-generating electronic components. The customizable air guide may be used to prevent unwanted cold air head loss (i.e., pressure loss) where cold air passes adjacent to an obstruction such as the end of a longer, adjacent electronic component that extends out beyond the front end of an adjacent, shorter electronic component supported within the same rack. Accordingly, the air guide may be used to isolate cold air flowing into the inlet and significantly reduce or prevent head loss from exposure to nearby structures.

The air guide may be formed from a sheet of material selected from plastic, cardboard and paper. Non-limiting examples of the plastic include polystyrene or phenolic material. In embodiments where the side panels are polymeric, the customizable air guide may be fabricated using a generally planar sheet of the polymeric material that is hot formed into a rectangular shape. A heated rectangular mold may be used to for this purpose. In one implementation, the duct comprises a sheet of material having three fold lines that define the four side panels.

Frangible links allow the length of the duct to be manually customized. These frangible links preferably extend perpendicular to the corners. The frangible links may be formed by any mechanical means, but may, for example, be selected from grooves and linear perforations. Optionally, the frangible links are V-shaped grooves. However, any of these frangible links are easily manually breakable along the path of the frangible link. The typical frangible link for use in the air guide will be substantially linear. In a preferred configuration, the duct has further frangible links formed along the corners of the duct that are formed between the four side panels. Frangible links running along the corner may be torn to allow other frangible links to be bent and broken.

The air guide may be secured in the air channeling configuration using a fastener such as a twist tie, wire, string, strap, rubber band, or adhesive. The generally planar material may have apertures through which a twist tie, wire, string or strap may be threaded to facilitate securing the lose edges after the side panels have been hot formed into the rectangular configuration. The apertures may be strategically located on the side panels so that the apertures are adjacent one to the other when the side panels are in rectangular configuration.

The air guides of the present invention may be disposed in a server rack to direct air flow to an electronic component having a length that is less than the full length of the server rack. As described previously, this prevents channeling of the air flow to adjacent components within the rack. The flange, which extends from the duct near along the front opening of the duct, is adapted for coupling to a front vertical rail of a standard server rack. For use with rack mountable components, the duct may, for example, have a cross-sectional dimension that is the same as a 1 U chassis, 2 U chassis, or any common component form factor.

One or more of the side panels may even comprise a cable port to facilitate the passage of data cables or power cables having a first end coupled to an electronic component adjacent to an outlet of the air guide and a second end coupled to another component within the server rack. The cable port may be open and without obstructions to air flow there through or it may be obstructed by bristles, extensions, filaments or portions of the original material left intact to obstruct air flow there through. Optionally, the cable port may comprise a serpentine cut forming a plurality of fingers that are closed unless a cable extends there through.

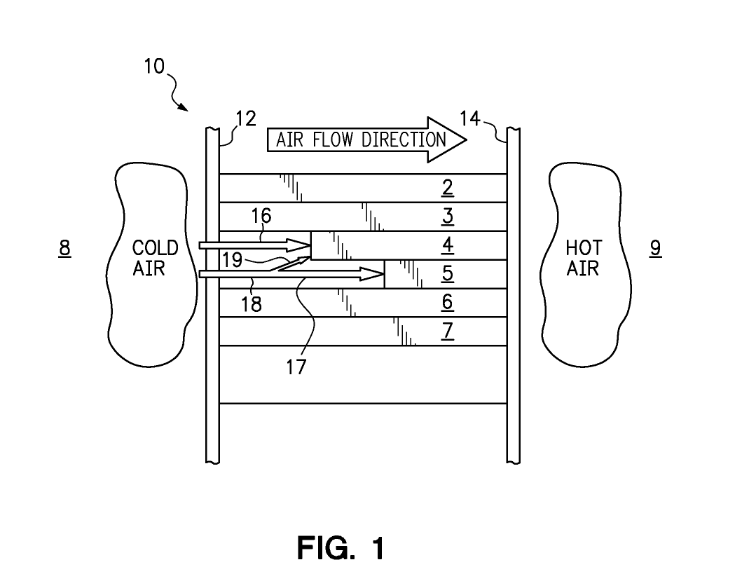

FIG. 1 is a side view of a server rack 10 supporting heat-generating electronic components 2-7 of varying lengths in a “stacked” configuration. As shown, the electronic components have varying lengths and present an uneven profile facing the front of the rack. The server rack 10 comprises a front pair of rails 12 adjacent to a cold air aisle 8 and a back pair of rails 14 adjacent to a hot air aisle 9. The heat-generating components 2-7 are supported in the server rack 10 by the vertical rails 12, 14 located at the corners of the server rack 10. Cold air is drawn into the components 2-7 along the front of the server rack 10, passes through the heat-generating components 2-7 picking up heat, and emerges from the heat-generating components 2-7 along the back of the server rack 10 into the hot air aisle 9. An air mover (not shown) is generally used to cause this air flow pattern, but may include fans within individual components, chassis or racks as well as a computer room air conditioner (CRAC).

Ideally, air from the cold aisle 8 is evenly distributed among the heat-generating components 2-7, so that each heat-generating component has access to adequate cold air. For example, the rate of cold air flow 16 through a first electronic component 4 is preferably approximately equal to the rate of cold air flow 19 through the second adjacent component 5. However, the distribution of cold air flow from the cold aisle 8 to the heat-generating components 2-7 may be impaired by irregularities such as the uneven lengths of adjacent components 4, 5 forming in an uneven profile facing the cold air aisle 8. As a result, the upstream component 4 receives a redirected portion 19 of the cold air path 18 that is intended for the more distant downstream component 5, and upstream component 4 receives an excessive rate of cold air flow approximately equal to the cold air flow 16 intended for the upstream component 4 plus the redirected portion 19 of the cold air flow 18. The amount of cold air flow 17 actually received by the downstream component 5 is reduced by a corresponding amount.

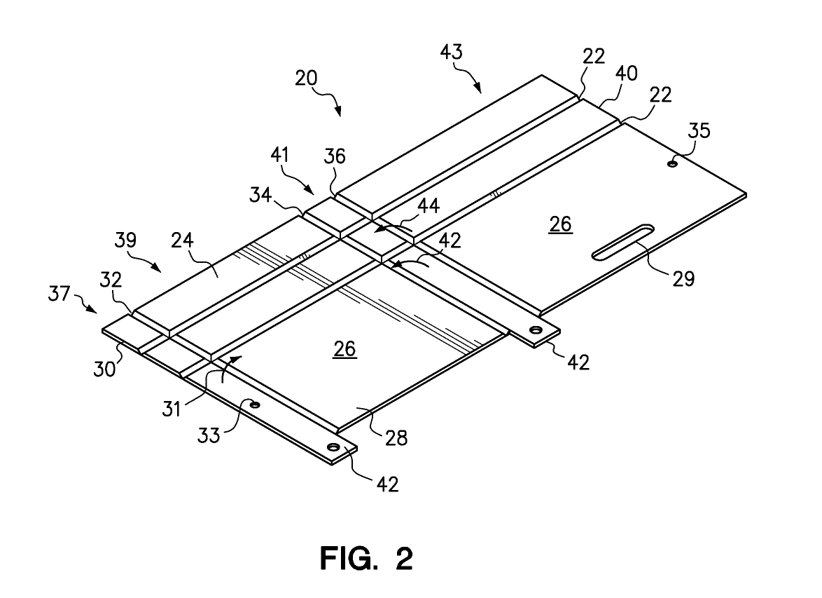

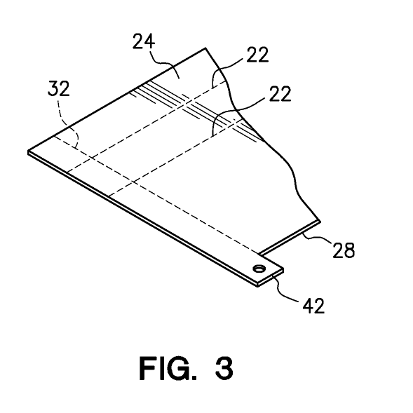

FIGS. 2-7 illustrate a solution to the problem illustrated in FIG. 1. FIG. 2 is a perspective view of a planar member 20 having a plurality of parallel frangible links 22. The frangible links 22 are breakable by bending to customize the length of an air guide to be made from the planar member 20. The frangible links 22 are shown as V-shaped grooves that extend transversely in a straight line from one side of the planar member 20 to the other side of the planar member. While two of the transverse frangible links 22 are shown, any number of transverse frangible links may be included with any desired spacing. Preferably, the transverse frangible links 22 are arranged at spaced intervals from a back edge 24 to allow the length of the air guide to be manually customized by removing portions of the planar member 20. The size of the removable portions is determined by the spacing of the links, and the distance from the links to the front edge 28 determines the possible lengths of the air guide. There is also preferably a region 26 near a front edge 28 that does not have frangible links. Accordingly, the region 26 has increased strength and greater rigidity. Alternative transverse frangible links 22 and longitudinal frangible links 32 are shown in FIG. 3 as linear perforations, which serve in the same manner as V-shaped grooves to enable the planar member to be manually broken at predetermined locations.

The planar member 20 further includes longitudinal frangible links 32, 34, 36 that assist in folding of the planar member or sheet 20 into a rectangular duct. Accordingly, the longitudinal frangible links 32, 34, 36 will also lie in the corners of the rectangular duct once formed.

The planar member 20 may optionally comprise apertures 33, 35 strategically located on the planar member 20 to be disposed one adjacent to the other after folding to form an air guide as will be described in more detail below. Still further, the planar member 20 may optionally comprise a cable port 29 to facilitate passage of a data cable or a power cable as will be described in more detail below.

Still further, the planar member 20 includes a pair of tabs 42 extending from the front edge 28. When the air guide has been formed, the tabs 42 will extend from opposing side panels of the air guide and may be bent to the side to form flanges 42. These flanges 42 can be used to secure the air guide to the rails of a rack.

The planar member 20 comprises a first end 30 and a second end 40, and may be folded along fold lines 32, 34, 36 to form a rectangular air guide. A first longitudinal frangible link 32, a second longitudinal frangible link 34, and a third longitudinal frangible link 36 can be strategically located within the planar member 21 to produce an air guide with four side panels 37, 39, 41, 43.

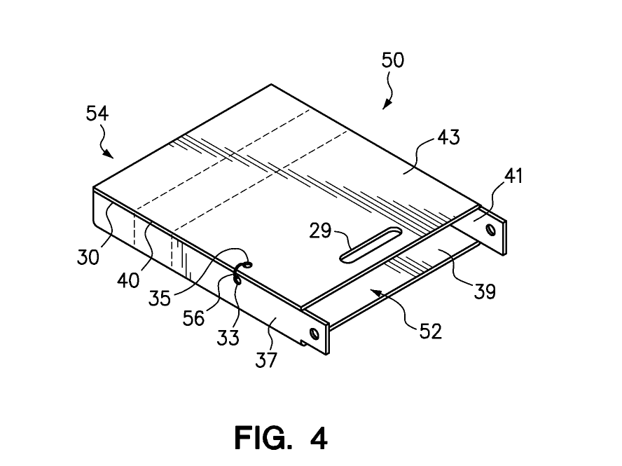

The sequence of folding of the planar member 21 along fold lines 32, 34, 36 to form an air guide is arbitrary, and the air guide may be formed by folding along the fold lines in any sequence. For example, a first side panel 37 (between the first end 30 and the first longitudinal frangible link 32) may be folded along the first longitudinal frangible link 32 in the direction indicated by the arrow 31; a second side panel 43 (between the second end 40 and the third longitudinal frangible link 36) may be folded along the third longitudinal frangible link 36 in the direction indicated by the arrow 44; and a third side panel 41 (between the second longitudinal frangible link 34 and the third longitudinal frangible link 36) may be folded along the second longitudinal frangible link 34 and in the direction indicated by the arrow 42 to form the air guide 50. (See FIG. 4).

FIG. 4 is a perspective view of an air guide 50 having an inlet 52 and an outlet 54. Folding the planar member 20 of FIG. 2 in the manner described above results in the first end 30 of the planar member being positioned adjacent to the second end 40 and the apertures 33, 35 being disposed one adjacent to the other. The now-adjacent apertures 33, 35 may receive a twist tie 56 to secure the first end 30 adjacent to the second end 40 and to secure the air guide 50 in an air channeling configuration. Alternatively, where the planar member is made of a plastic material, the twist tie may be replaced by a “spot weld” melting the plastic at that point. The cable port 29 of the air guide 50 is positioned near the inlet 52.

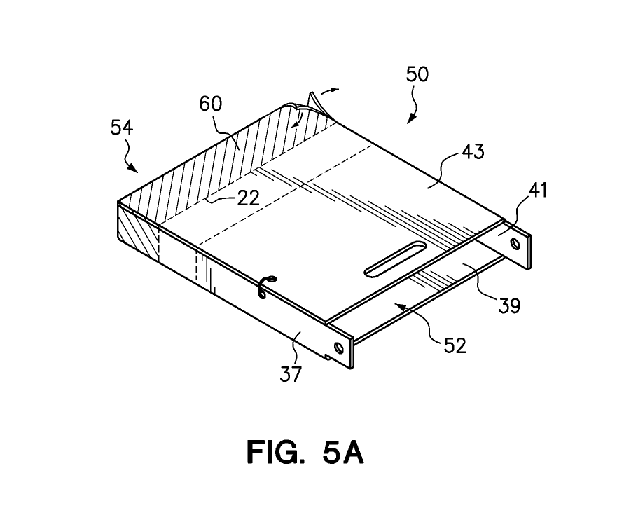

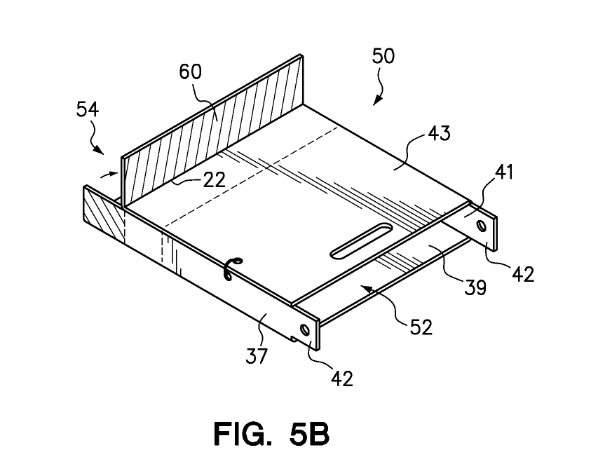

FIG. 5A is a perspective view of the rectangular air guide 50. In order to shorten the guide 50, a portion of the guide is to manually broken, torn, or otherwise removed from the duct. As shown, the portion of the guide to be removed is determined by the selection of the transverse frangible link 22 that will be broken. The portion to be removed is drawn here with diagonal lines. It should be recognized that a portion of each side panel 37, 39, 41, 43 will be removed to leave a back edge of the guide 50 that will fit up against an electronic component.

As shown in FIG. 5A, a corner between the two side panels 41, 43 is torn from the back edge up to the first transverse frangible link 22. This allows a portion 60 of side panel 43 to be folded upward to be broken off. FIG. 5B is a perspective view of the rectangular air guide 50 with the portion 60 folded upward to where it can be broken off. Successive portions of the other side panels 37, 39, 41 may be folded and broken off until the air guide 50 has been shortened. It should be recognized that this process may be performed with selection a different transverse frangible link, or repeated as necessary to achieve a desired length. By removing portions from the back of the air guide, the front region 24 remains strong and the flanges 42 are never removed.

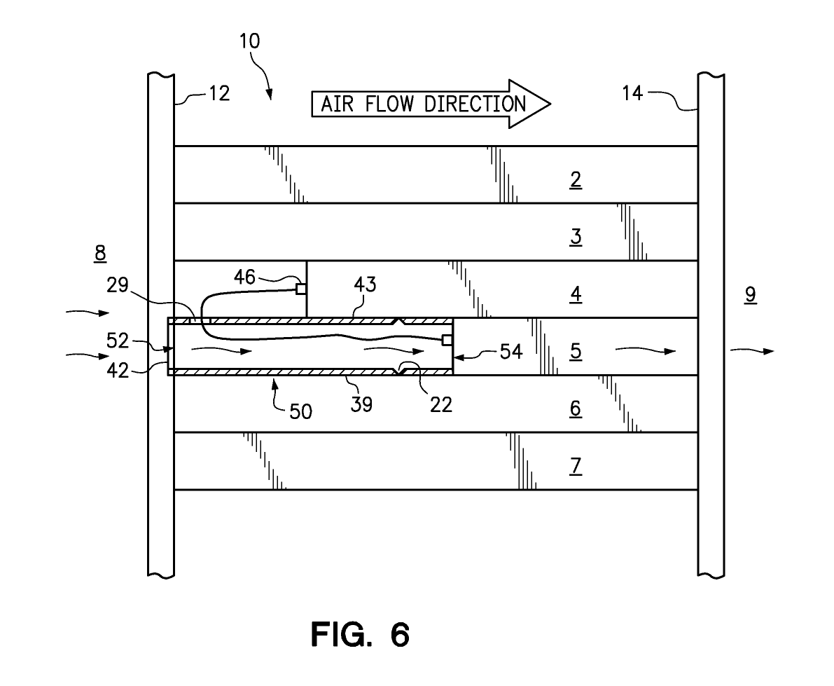

FIG. 6 is a partial cross-sectional side view of the rack 10 of FIG. 1 after installation of the air guide 50 into the rack in alignment with the electronic component 5. The air guide 50 directs cold air flow from the cold air aisle 8 to the front of the downstream component 5. Specifically, the inlet 52 is positioned upstream (as the air flows) of the adjacent end of component 4 so that cold air flows from the cold air aisle 8, enters the inlet 52 of the air guide 50, passes through the air guide 50, exits the outlet 54 of the air guide 50, and then flows through the downstream component 5 to remove heat generated therein. The cable port 29 is positioned between the inlet 52 of the air guide 50 and the end of the upstream component 4 to facilitate passage of a data cable or power cable from component 5 through the cable port 29 to, for example, component 4.

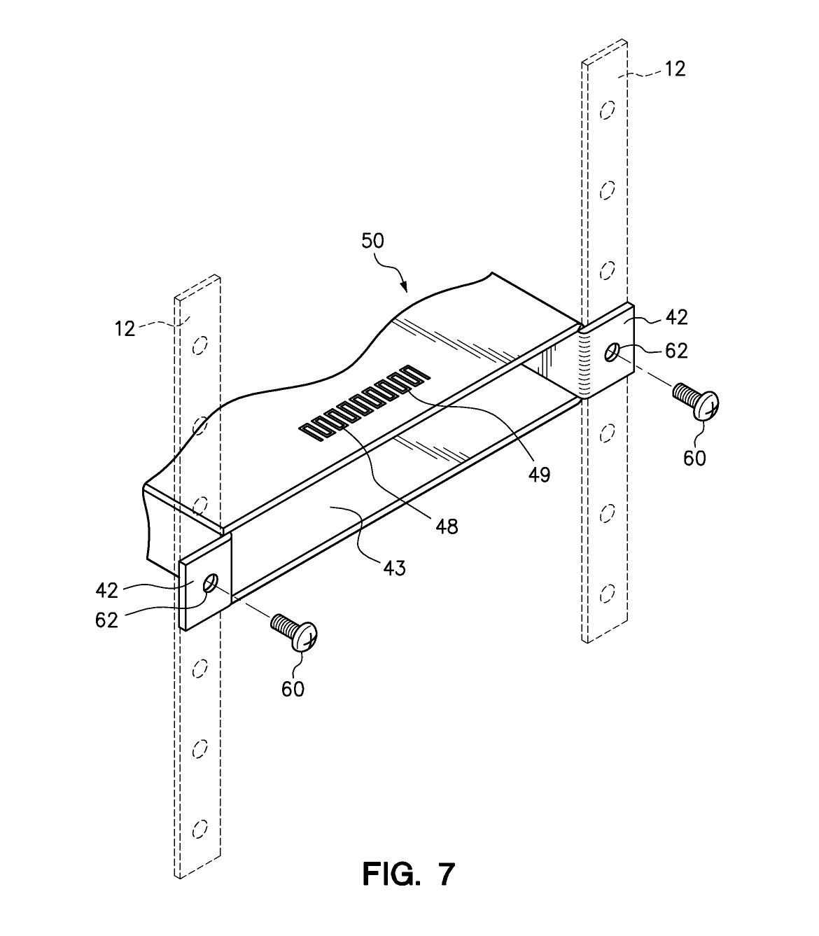

FIG. 7 is a perspective view of the front end of the air guide 50 with its two flanges 42 folded laterally and extending across the front of the vertical rails 12 at the front of the rack. Note that the two flanges 42 may be preformed during the fabrication of the air flow guide as shown in FIG. 4. In this position, fasteners 60 may be used to secure the flanges 42 to the respective rails 12. Where the vertical rails 12 are part of a standard rack, the holes 62 may have the same spacing and diameter to facilitate attachment. Although the air guide 50 has been illustrated as having a 1 U form factor for guiding air to a 1 U component 5, the invention is similarly applicable to an air guide having a 2 U form factor for guiding air to a 2 U component (not shown). Such a 2 U air guide may, if desired, have flanges with two holes each further securing to a rail.

FIG. 7 also illustrates an alternate embodiment of a cable port 49 formed using a corrugated blade (not shown) or a blade having one or more edges that follows a serpentine path. Unlike a punch blade or punch member that may be used to provide the cable port 29 illustrated in FIG. 4, the alternate embodiment of the air guide 250 illustrated in FIG. 7 comprises an obstructed cable port 49 that facilitates the threading of a cable (not shown) through the cable port 49 while retaining at least some interior obstruction, such as fingers 48, that will obstruct the passage of cold air either from or into the air guide 50.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, components and/or groups, but do not preclude the presence or addition of one or more other features, integers, steps, operations, elements, components, and/or groups thereof. The terms “preferably,” “preferred,” “prefer,” “optionally,” “may,” and similar terms are used to indicate that an item, condition or step being referred to is an optional (not required) feature of the invention.

The corresponding structures, materials, acts, and equivalents of all means or steps plus function elements in the claims below are intended to include any structure, material, or act for performing the function in combination with other claimed elements as specifically claimed. The description of the present invention has been presented for purposes of illustration and description, but it is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. A user-customizable air guide, comprising:
a duct having four side panels, an open front end, an open back end, and a flange extending from at least two of the side panels at the front end, wherein the four side panels have a plurality of frangible links that are generally parallel and spaced apart along the rectangular duct between the front end and the back end, wherein each frangible link extends around the four side panels of the rectangular duct, and wherein the frangible links are manually breakable to customize the length of the duct extending from the open front end.

2. The air guide of claim 1, wherein the duct has a frangible link formed along three corners that are formed between the four side panels.

3. The air guide of claim 1, wherein the frangible links are selected from grooves and linear perforations.

4. The air guide of claim 1, wherein the frangible links are V-shaped grooves.

5. The air guide of claim 1, wherein the duct comprises a sheet of material having three fold lines that define the four side panels.

5. The air guide of claim 5, wherein the sheet of material is a plastic that has been hot formed around a rectangular mold.

6. The air guide of claim 5, further comprising:
a fastener to secure a first edge panel to a second edge panel.

7. The air guide of claim 5, wherein the plurality of frangible links extend perpendicular to the corners.

8. The air guide of claim 1, wherein the
wherein the air guide may be disposed in a server rack to direct air flow to an electronic component having a depth that is less than the server rack depth.

9. The air guide of claim 8, wherein the flange is adapted for coupling to a front vertical rail of a standard server rack.

10. The air guide of claim 9, wherein the duct has a cross-sectional dimension that is the same as a 1 U chassis.

11. The air guide of claim 9, wherein the duct has a cross-sectional dimension that is the same as a 1 U chassis.

12. The air guide of claim 1, wherein the side panels comprise a sheet of plastic material.

13. The air guide of claim 1, wherein the side panels comprise a sheet of cardboard or paper.

14. The air guide of claim 1, wherein the at least one of the side panels comprises a cable port to allow passage of a data cable to the electronic component from an adjacent electronic component.

15. The air guide of claim 14, wherein the cable port comprises a serpentine cut forming a plurality of fingers that are closed unless a cable extends therethrough.

16. The air guide of claim 1, wherein the side panels are made from sheet of polystyrene or phenolic resin.
